(19) United States
(12) Patent Application Publication
(10) Pub. No.: US 2014/0056092 A1
(43) Pub. Date: Feb. 27, 2014

(54) SEMICONDUCTOR MEMORY DEVICE AND METHOD OF OPERATING THE SAME

(71) Applicant: SK HYNIX INC., Icheon-si (KR)

(72) Inventor: Hee Youl LEE, Icheon-si (KR)

(73) Assignee: SK hynix Inc., Icheon-si (KR)

(21) Appl. No.: 13/720,249

(22) Filed: Dec. 19, 2012

(30) Foreign Application Priority Data
Aug. 24, 2012 (KR) 10-2012-0093170

(51) Int. Cl. G11C 7/00

(52) U.S. Cl. CPC G11C 7/00
USPC 365/218

(57) ABSTRACT

A semiconductor memory device, comprising a memory cell block configured to include word lines disposed between a drain select line and a source select line, a voltage generation circuit configured to generate a compensation voltage when an erase operation is performed, and a row decoder configured to apply the compensation voltage to word lines adjacent to each of the drain select line and the source select line, and apply a word line voltage less than the compensation voltage to the other word lines, and a method of operating the same are disclosed.

### CROSS-REFERENCE TO RELATED APPLICATION

This application claims priority from Korean Patent Application No. 10-2012-0093170, filed on Aug. 24, 2012, the contents of which are incorporated herein by reference in its entirety.

### BACKGROUND MODE OF THE INVENTION

The present invention relates generally to a semiconductor memory device and method of operating the same, and more particularly relates to an erase operation.

A semiconductor memory device includes a memory cell array having memory cells for storing data, circuits for performing a program operation, a read operation and an erase operation, and a control circuit for controlling the circuits.

Hereinafter, the memory cell array will be described in detail.

The memory cell array includes memory cell blocks, and the memory cell blocks have cell strings. Each of the cell strings includes a drain select transistor, memory cells and a source select transistor connected in serial. A drain of the drain select transistor is connected to a bit line, and a source of the source select transistor is connected to a common source line. Gates of the drain select transistors included in the cell strings are connected to a drain select line, and gates of the source select transistors are connected to a source select line. Gates of the memory cells are connected to word lines.

To meet demands for smaller memory devices with increased functionality, efforts to reduce the size of the drain select transistor, the memory cells and the source select transistor and to increase the integrity of the semiconductor memory device are made. However, the reliability of the program operation, the read operation and the erase operation may be lowered.

In the erase operation, an erase voltage is applied to a well, the drain select line and the source select line of a selected memory cell block are floating, and 0V is applied to the word lines. Potential of the drain select line and the source select line adjacent to each of outmost word lines may decrease due to the 0V applied to the outmost word lines. As a result, the potential difference between the drain and the source select lines and the well increases, which may cause damage to the drain select transistor and the source select transistor. Additionally, a potential difference between the drain and the source select lines and the outmost word lines may exist. As the potential difference between the drain and the source select lines and the outmost word lines increases, an electrical field augments. As a result, leakage current of the drain select transistor and the source select transistor may increase, and a breakdown of the transistors may occur.

Thus, reliability of the semiconductor memory device may be lowered.

### SUMMARY OF THE INVENTION

Various embodiments of the present invention provide a semiconductor memory device for improving the reliability of an erase operation and a method of operating the same.

A semiconductor memory device according to an embodiment of the present invention includes a memory cell block configured to include word lines disposed between a drain select line and a source select line; a voltage generation circuit configured to generate a compensation voltage when an erase operation is performed; and a row decoder configured to apply the compensation voltage to word lines adjacent to each of the drain select line and the source select line, and apply a word line voltage less than the compensation voltage to the other word lines.

A semiconductor memory device according to another embodiment of the present invention includes a memory cell block configured to include word lines disposed between a source select line and a drain select line, first dummy lines disposed between the source select line and the word lines, and second dummy lines between the drain select line and the word lines; a voltage generation circuit configured to generate a compensation voltage when an erase operation is performed; and a row decoder configured to apply the compensation voltage to outmost word lines adjacent to each of the first dummy lines and the second dummy lines of the word lines, and apply a word line voltage less than the compensation voltage to the other word lines.

A method of operating a semiconductor memory device according to another embodiment of the present invention includes applying an erase voltage to a well of a selected memory cell block in an erase operation; floating a drain select line and a source select line; applying a word line voltage to all word lines excluding outmost word lines adjacent to each of the drain select line and the source select line; and applying a compensation voltage greater than the word line voltage to the outmost word lines.

A method of operating a semiconductor memory device according to another embodiment of the present invention includes applying an erase voltage to a well of a selected memory cell block in an erase operation; floating a drain select line, a source select line, first dummy lines disposed between the source select line and word lines and second dummy lines disposed between the drain select line and the word lines; applying a word line voltage to the other word lines excluding outmost word lines adjacent to each of the first dummy lines and the second dummy lines; and applying a compensation voltage greater than the word line voltage to the outmost word lines.

In an erase operation of the present invention, a compensation voltage is applied to a word line or a dummy line adjacent to a floating line, thereby reducing damage on a transistor connected to the floating line. As a result, reliability of the erase operation may be improved.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a block diagram illustrating a semiconductor memory device according to an embodiment of the present invention;

FIG. 2 is a view illustrating a circuit diagram of a memory cell block for an erase operation according to an embodiment of the present invention;

FIG. 3 is a view illustrating circuit diagram of a memory cell block for an erase operation according to another embodiment of the present invention; and

FIG. 4 is a view illustrating circuit diagram of a memory cell block for an erase operation according to another embodiment of the present invention.

### DESCRIPTION OF SPECIFIC EMBODIMENTS

Hereinafter, the preferred embodiments of the present invention will be explained in more detail with reference to the accompanying drawings. Although embodiments have been described with reference to a number of illustrative embodiments thereof, it should be understood that numerous other modifications and embodiments can be devised by those skilled in the art that will fall within the spirit and scope of the principles of this disclosure.

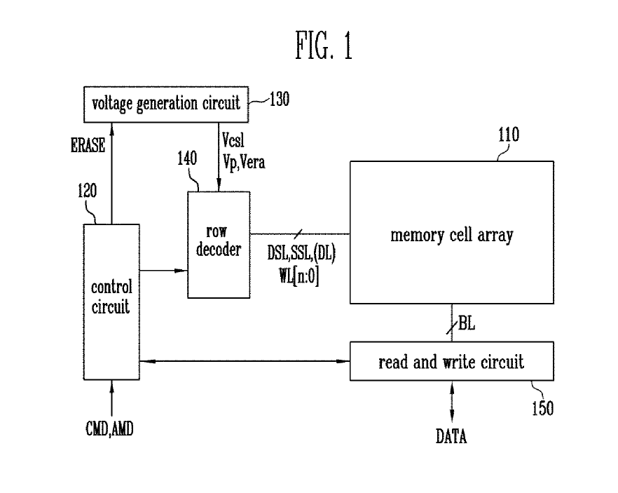

FIG. 1 is a block diagram illustrating a semiconductor memory device according to one example embodiment of the present invention.

In FIG. 1, the semiconductor memory device includes a memory cell array 110, circuits 130, 140 and 150 for performing a program operation, a read operation and an erase operation of memory cells in the memory cell array 110, and a control circuit 120 for controlling the circuits 130, 140 and 150 to perform the program operation, the read operation and the erase operation according to input data.

The circuits in a NAND flash memory device include a voltage generation circuit 130, a row decoder 140, and a read and write circuit 150.

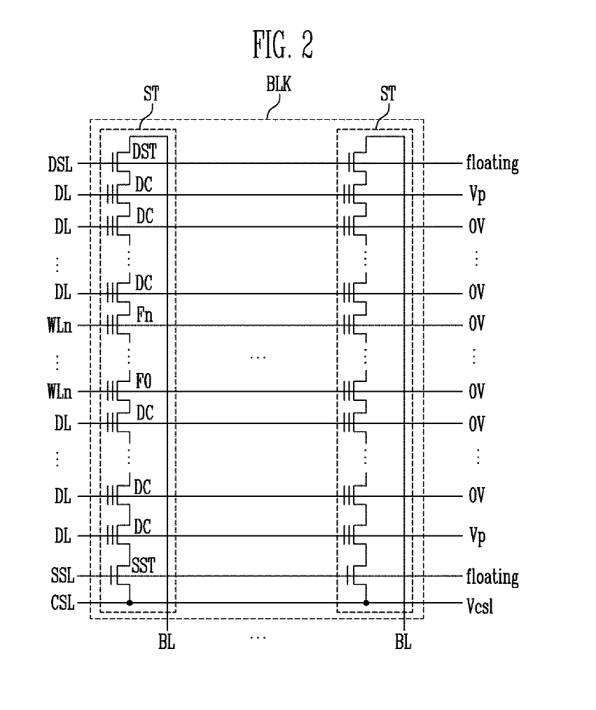

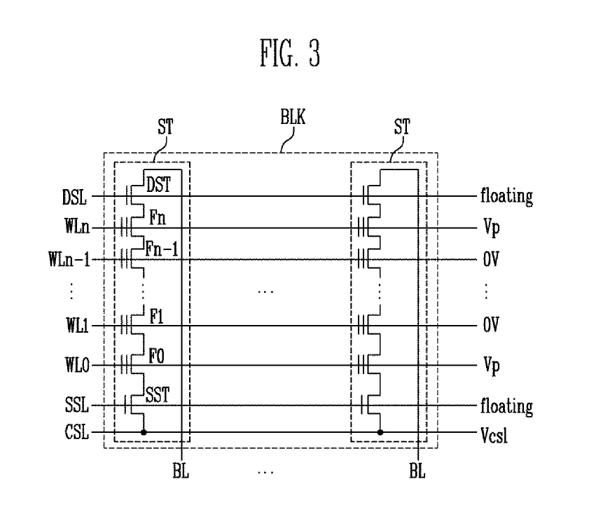

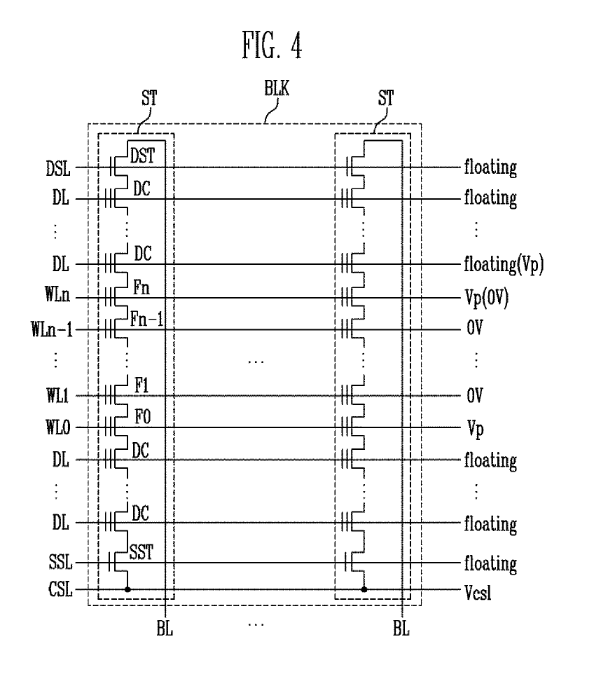

The memory cell array 110 includes memory cell blocks (not shown). The memory cell blocks will be described in detail with reference to accompanying drawings FIG. 2, FIG. 3 and FIG. 4.

The voltage generation circuit 130 generates needed voltage according to operation signals outputted from the control circuit 120. For example, when an erase operation signal ERASE is outputted from the control circuit 120, the voltage generation circuit 130 generates a drain select voltage Vdsl (not shown) applied to a drain select line, a source select voltage Vssl (not shown) applied to a source select line, a common source voltage Vcsl applied to a common source line and an erase voltage Vera applied to the well. In the erase operation, the voltage generation circuit 130 additionally generates a compensation voltage Vp to be applied to dummy lines or outmost word lines. If dummy lines do not exist, the outmost word lines refer to word lines adjacent to each of the drain select line and the source select line. If dummy lines are connected between the drain select line and the word line and/or between the source select line and the word line, the outmost word lines refer to word lines adjacent to each of the dummy lines. The compensation voltage Vp is a voltage applied to the dummy lines or the outmost word lines to prevent the lowering of potential of the drain select line and the source select line in the erase operation. The compensation voltage Vp has a positive level, e.g. the compensation voltage Vp may have a voltage greater than a voltage applied to the word lines by 1V to 4V in the erase operation.

The row decoder 140 selects a memory cell block according to control of the control circuit 120, and delivers the voltages generated from the voltage generation circuit 130 to the drain select line DSL, the source select line SSL, the word lines WL[n:0] and the dummy lines DL connected to a selected memory cell block. For example, in the erase operation, the row decoder 140 delivers the erase voltage Vera to the well, applies the compensation voltage Vp to the dummy lines DL or the outmost word lines WL0 and WLn, and floats the drain select line DSL and the source select line SSL of the selected memory block. Further, the row decoder 140 floats the common source line CSL or applies the common source voltage Vcsl having positive voltage or a ground voltage to the common source line CSL.

The read and write circuit 150 applies a program allowable voltage, e.g. 0V or a program inhibition voltage, e.g. Vcc (not shown) to bit lines BL connected to the memory cell array 110 according to control of the control circuit 120 and data DATA inputted from an outside device. The read and write circuit 150 outputs data read from the memory cell array 110 to an outside device according to control of the control circuit 120. In the erase operation, the read and write circuit 150 applies a voltage corresponding to the program inhibition voltage to the bit lines BL.

The control circuit 120 outputs internal operation signals in response to a command signal CMD, and controls the row decoder 140 and the read and write circuit 150. For example, when the command signal CMD for the erase operation is inputted, the control circuit 120 outputs an erase operation signal ERASE and controls the row decoder 140 and the read and write circuit 150 to perform the erase operation.

FIG. 2 is a view illustrating a circuit diagram of a memory cell block for an erase operation according to an embodiment of the present invention.

In FIG. 2, the memory cell block BLK of the present embodiment is as follows.

The memory cell block BLK includes cell strings ST. Since the cell strings ST have the same constitution, one cell string ST will be described as a representative of the cell strings ST.

The cell string ST includes a source select transistor SST, dummy cells DC, memory cells F0-Fn, and a drain select transistor DST collectively connected in serial between a common source line CSL and a bit line BL. The dummy cells DC have the same constitution as the memory cells F0-Fn, and the cell string ST may include one or more dummy cells DC. Gates of source select transistors SST included in the cell strings ST are connected to a source select line SSL, gates of the drain select transistors DST are connected to a drain select line DSL, gates of the dummy cells DC are connected to the dummy lines DL, and gates of the memory cells F0-Fn are connected to word lines WL0-WLn, respectively.

An erase operation of the present invention is as follows. When the erase operation starts, an erase voltage is applied to the well, and a word line voltage is applied to the word lines WL0-WLn. For example, the word line voltage is 0V. The drain select line DSL and the source select line SSL are floating. The compensation voltage Vp is applied to dummy lines DL adjacent to each of the drain select line DSL and the source select line SSL, thus reducing damage to the drain select transistor DST and the source select transistor SST.

Equation 1 shows the potential of the drain select transistor DST and the source select transistor SST.

Vsel=(Ksw×Vwl)+(Kss×Vpw) [Equation 1]

where ‘Vsel’ is the potential of a select line, ‘Ksw’ a is capacitance coupling ratio between the select line and a word line adjacent to the select line, ‘Vwl’ is a voltage applied to the word line adjacent to the select line, ‘Kss’ is a capacitance coupling ratio between a select transistor and a well, and ‘Vpw’ is a voltage applied to the well.

Hereinafter, the potential of the drain select line DSL when the compensation voltage Vp is not applied and potential of the drain select line DSL when the compensation voltage Vp is applied will be compared with consideration of Equation 1.

An erase operation of the semiconductor memory device when the memory cell array does not include the dummy lines DL and the compensation voltage Vp is not applied is described as follows.

In the semiconductor memory device where a breakdown voltage between the select lines DSL and SSL and the outmost word lines WL0 and WLn is 13V and a breakdown voltage between the select lines DSL and SSL and the well is 6V, it is assumed that ‘Ksw’ is 0.3 and ‘Kss’ is 0.7. Generally, in the erase operation, the erase voltage, e.g. 20V is applied to the well, the drain select line DSL is floating, and the word line voltage, e.g. 0V is applied to every word line WL. The potential Vsel of the drain select line DSL is (0.3×0V)±(0.7×20V), i.e. 14V according to Equation 1. The potential difference between the drain select line DSL and the adjoining word line WLn is (14V-0V), i.e. 14V, and the potential difference between the drain select line DSL and the well is 20V-14V, i.e. 6V. As a result, a breakdown of the drain select transistor DST may occur. Thus, if an area where the source select transistor SST is formed has the same electrical characteristics as an area where the drain select transistor DST is formed, a breakdown of the source select transistor SST may occur.

In another embodiment of the present invention, the memory cell array includes dummy lines DL as shown in FIG. 2. An erase operation when the compensation voltage Vp is applied is described as follows.

In the semiconductor memory device where a breakdown voltage between the select lines DSL and SSL and the outmost word lines WL0 and WLn is 13V and a breakdown voltage between the select lines DSL and SSL and the well is 6V, it is assumed that ‘Ksw’ is 0.3 and ‘Kss’ is 0.7. In the erase operation, an erase voltage, e.g. 20V is applied to the well, the drain select line DSL is floating, and the word line voltage, e.g. 0V is applied to every word line WL0-WLn. The common source line CSL is floating or the common source voltage Vcsl having positive voltage may be applied to the common source line CSL. 0V is applied to the other dummy lines excluding the dummy lines DL adjacent to each of the drain select line DSL and the source select line SSL. The compensation voltage Vp for minimizing damage to the drain select transistor DST and the source select transistor SST is applied to the dummy lines DL adjacent to each of the drain select line DSL and the source select line SSL. The compensation voltage Vp may be greater than the voltage applied to the word lines WL0-WLn by 1V to 4V. For example, the compensation voltage Vp may be 2V as positive voltage. Accordingly, the potential of the drain select line DSL equates to (0.3×2V)±(0.7×20V), i.e. 14.6V according to Equation 1, and the potential of the source select line SSL is 14.6V. The potential difference between the dummy line DL adjacent to the drain select line DSL and the drain select line DSL is 14.6V-2V, i.e. 12.6V, and thus it is lower by 1.4V when compared to the potential difference of 14V when the compensation voltage Vp was not applied. Additionally, since the potential difference between the drain select line DSL and the well equates to 20V-14.6V, i.e. 5.4V, it is lower by 0.6V when compared to the potential difference of 6V when the compensation voltage Vp was not applied. Accordingly, a breakdown of the drain select transistor DST may not occur by applying the compensation voltage Vp to the dummy line DL adjacent to the a floating drain select line DSL. Breakdown of the source select transistor SST may also not occur through the above method.

FIG. 3 is a view illustrating a circuit diagram of a memory cell block for an erase operation according to another embodiment of the present invention.

Referring to FIG. 3, the memory cell block BLK of the present embodiment is as follows.

The memory cell block BLK includes cell stings ST. Since the cell strings ST have the same constitution, one cell string ST will be described as a representative of the cell strings ST.

The cell string ST includes a source select transistor SST, memory cells F0-Fn and a drain select transistor DST collectively connected in serial between a common source line CSL and a bit line BL. Gates of the source select transistors SST included in different cell strings ST are connected to a source select line SSL, gates of the drain select transistors DST are connected to a drain select line DSL, and gates of the memory cells F0-Fn are connected to word lines WL0-WLn, respectively.

An erase operation according to this embodiment of the present invention is as follows. When the erase operation starts, an erase voltage is applied to the well, and the drain select line DSL and the source select line SSL are floating. The common source line CSL may either be floating or have the common source voltage Vcsl applied. A word line voltage, e.g. 0V is applied to the other word lines WL1-WLn−1 (not word lines WL0 and WLn) adjacent to each of the drain select line DSL and the source select line SSL, and a compensation voltage Vp for reducing damage to the select transistors DST and SST is applied to the word lines WL0 and WLn adjacent to each of the drain select line DSL and the source select line SSL.

Equation 1 shows the potential of the drain select line DSL according to the second embodiment considering Equation 1 is as follows. Unlike the first embodiment where the compensation voltage Vp is applied to the dummy lines DL adjacent to each of the drain select line DSL and the source select line SSL which are floating, the compensation voltage Vp in this embodiment is applied to outmost word lines WL0 and WLn of the word lines WL0-WLn because the dummy lines are not included. It is assumed that a voltage applied to the drain select line DSL is identical to that applied to the source select line SSL in the erase operation, and that the drain select transistor DST has the same potential as the source select transistor SST.

In the semiconductor memory device where a breakdown voltage between the select lines DSL and SSL and the outmost word lines WL0 and WLn adjacent to each of the select lines DSL and SSL is 13V and a breakdown voltage between the select lines DSL and SSL and the well is 6V, it is assumed that ‘Ksw’ is 0.3 and ‘Kss’ is 0.7. In the erase operation, an erase voltage, e.g. 20V is applied to the well, the drain select line DSL is floating, and the word line voltage, e.g. 0V is applied to every word line WL0-WLn. The word line voltage, e.g. 0V is applied to the other word lines WL1-WLn (not the outmost word lines WL0 and WLn) adjacent to each of the drain select line DSL and the source select line SSL. The compensation voltage Vp for minimizing damage to the drain select transistor DST and the source select transistor SST is applied to the outmost word lines WL0 and WLn adjacent to each of the drain select line DSL and the source select line SSL. The compensation voltage Vp may be greater than the voltage applied to the other word lines WL1-WLn−1 by 1V to 4V. For example, the compensation voltage Vp may be 2V as positive voltage. Accordingly, the potential of the drain select line DSL equates to (0.3×2V)±(0.7×20V), i.e. 14.6V according to Equation 1, and thus the potential of the source select line SSL is 14.6V. The potential difference between the word line WLn adjacent to the drain select line DSL and the drain select line DSL is 14.6V-2V, i.e. 12.6V, and thus it is lower by 1.4V when compared to the potential difference of 14V when the compensation voltage Vp is not applied. Additionally, since the potential difference between the drain select line DSL and the well equates to 20V-14.6V, i.e. 5.4V, it is lower by 0.6V when compared to the potential difference of 6V when the compensation voltage Vp is not applied. Accordingly, a breakdown of the drain select transistor DST may not occur by applying the compensation voltage Vp to the word line WLn adjacent to a floating drain select line DSL. Breakdown of the source select transistor SST also may not occur through the above method.

FIG. 4 is a view illustrating a circuit diagram of a memory cell block for an erase operation according to yet another embodiment of the present invention.

Referring to FIG. 4, the memory cell block BLK of the present embodiment is as follows.

The memory cell block BLK includes cell stings ST. Since the cell strings ST have the same constitution, one cell string ST will be described as a representative of the cell strings ST.

The cell string ST includes a source select transistor SST, dummy cells DC, memory cells F0-Fn and a drain select transistor DST collectively connected in serial between a common source line CSL and a bit line BL. The dummy cells DC have the same constitution as the memory cells F0-Fn, and the cell string ST may include one or more dummy cells DC. Gates of the source select transistors SST included in different cell strings ST are connected to a source select line SSL, gates of the drain select transistors DST are connected to a drain select line DSL, gates of the dummy cells DC are connected to dummy lines DL, and gates of the memory cells F0-Fn are connected to word lines WL0-WLn, respectively.

An erase operation according to this embodiment is as follows. When the erase operation starts, an erase voltage is applied to the well, and the drain select line DSL, the source select line SSL and the dummy lines DL all become floating. The common source line CSL may either be floating or have the common source voltage Vcsl having a positive voltage applied. If the dummy lines DL adjacent to each of the drain select line DSL and the source select line SSL also become floating, the potential difference between the drain select line DSL and the dummy line DL adjacent to the drain select line DSL does not generate, and thus breakdown of the drain select transistor DST does not occur. In addition, since the potential difference between the source select line SSL and the dummy line DL adjacent to the source select line SSL does not generate, breakdown of the source select transistor SST does not occur. A word line voltage, e.g. 0V may be applied to word lines WL0-WLn, and the compensation voltage Vp may be applied to outmost word lines WL0 and WLn adjacent to the dummy lines DL to reduce damage to the dummy cells DC adjacent to each of the word lines WL0 and WLn. That is, the dummy lines DL become floating in this embodiment, preventing breakdown of the select transistors DST and SST, and further preventing breakdown of the dummy lines DL by applying the compensation voltage Vp to the outmost word lines WL0 and WLn.

The potential of the dummy lines DL according to this embodiment considering Equation 1 is as follows. In the semiconductor memory device where a breakdown voltage between the select lines DSL and SSL and the outmost word lines WL0 and WLn adjacent to each of the select lines DSL and SSL is 13V and a breakdown voltage between the dummy lines DL and the well is 6V, it is assumed that ‘Ksw’ is 0.3 and ‘Kss’ is 0.7. In the erase operation, an erase voltage, e.g. 20V is applied to the well, the drain select line DSL, the source select line SSL and the dummy lines DL are all floating, and the word line voltage, e.g. 0V is applied to the other word lines WL1-WLn−1 (not the outmost word lines WL0 and WLn), and the compensation voltage Vp is applied to the outmost word lines WL0 and WLn to minimize damage to the dummy lines DL. The compensation voltage Vp may be greater than the voltage applied to the other word lines WL1-WLn−1 by 1V to 4V. For example, the compensation voltage Vp may be 2V as a positive voltage. Accordingly, the potential of the dummy lines DL equates to (0.3×2V)+(0.7×20V), i.e. 14.6V according to Equation 1. The potential difference between the dummy lines DL adjacent to the outmost word lines WL0 and WLn and the outmost word lines WL0 and WLn is 14.6V-2V, i.e. 12.6V, and thus it is lower by 1.4V when compared to the potential difference of 14V when the compensation voltage Vp is not applied. Additionally, since the potential difference between the dummy lines DL and the well equates to 20V-14.6V, i.e. 5.4V, it is lower by 0.6V when compared to the potential difference of 6V when the compensation voltage Vp is not applied. Accordingly, breakdown of the dummy cells DC connected to the dummy lines DL may not occur by applying the compensation voltage Vp to the floating outmost word lines WL0 and WLn adjacent to the dummy lines DL.

Since a compensation voltage Vp greater than the voltage applied to the other word lines WL1-WLn−1 is applied to the outmost word lines WL0 and WLn in the erase operation, the erase operation of the memory cells F0 and Fn connected to the outmost word lines WL0 and WLn may not be performed normally, such that the erase operation for the memory cells F0 and Fn connected to the outmost word lines WL0 and WLn may be further performed. For example, if the erase operation of the memory cells F1-Fn−1 connected to the word lines WL1-WLn−1 are finished while the erase operation is performed according to this embodiment, the erase operation for the memory cells F0 and Fn connected to the outmost word lines WL0 and WLn may be further performed by applying the word line voltage, e.g. 0V to the outmost word lines WL0 and WLn to which the compensation voltage Vp is applied and applying the compensation voltage Vp to the dummy lines DL adjacent to the outmost word lines WL0 and WLn.

As described above, the compensation voltage Vp is applied to the lines adjacent to the lines which are floating in the erase operation, and thus the potential difference between the lines adjacent to the lines which are floating and the lines which are floating may reduce. As a result, breakdown of the lines which are floating may be prevented, and so reliability of the erase operation may be improved.

Although embodiments have been described with reference to a number of illustrative embodiments thereof, it should be understood that numerous other modifications and embodiments can be devised by those skilled in the art that will fall within the spirit and scope of the principles of this disclosure.

What is claimed is:

1. A semiconductor memory device comprising:
a memory cell block configured to include word lines disposed between a drain select line and a source select line;
a voltage generation circuit configured to generate a compensation voltage when an erase operation is performed; and
a row decoder configured to apply the compensation voltage to word lines adjacent to each of the drain select line and the source select line, and apply a word line voltage less than the compensation voltage to the other word lines.

2. The semiconductor memory device of claim 1, wherein the row decoder floats the drain select line and the source select line, and applies an erase voltage to a well of the memory cell block.

3. The semiconductor memory device of claim 1, wherein the voltage generation circuit generates the word line voltage of 0V.

4. The semiconductor memory device of claim 3, wherein the voltage generation circuit generates the compensation voltage as being 1V to 4V greater than the word line voltage.

5. A semiconductor memory device comprising:
a memory cell block configured to include word lines disposed between a source select line and a drain select line, first dummy lines disposed between the source select line and the word lines, and second dummy lines between the drain select line and the word lines;
a voltage generation circuit configured to generate a compensation voltage when an erase operation is performed; and
a row decoder configured to apply the compensation voltage to outmost word lines adjacent to each of the first dummy lines and the second dummy lines of the word lines, and apply a word line voltage less than the compensation voltage to the other word lines.

6. The semiconductor memory device of claim 5, wherein the row decoder floats the drain select line, the source select line, the first dummy lines and the second dummy lines, and applies an erase voltage to a well of the memory cell block.

7. The semiconductor memory device of claim 6, wherein the row decoder further applies the word line voltage to the outmost word lines to erase memory cells connected to the outmost word lines after the erase operation is performed.

8. The semiconductor memory device of claim 7, wherein the row decoder applies the compensation voltage to dummy lines adjacent to each of the outmost word lines of the first dummy lines and the second dummy lines after the memory cells connected to the outmost word lines are erased.

9. The semiconductor memory device of claim 5, wherein the voltage generation circuit generates the word line voltage of 0V.

10. The semiconductor memory device of claim 9, wherein the voltage generation circuit generates the compensation voltage as being 1V to 4V greater than the word line voltage.

11. A method of operating a semiconductor memory device, the method comprising:
applying an erase voltage to a well of a selected memory cell block in an erase operation;
floating a drain select line and a source select line;
applying a word line voltage to all word lines excluding outmost word lines adjacent to each of the drain select line and the source select line; and
applying a compensation voltage greater than the word line voltage to the outmost word lines.

12. The method of claim 11, wherein the word line voltage is 0V.

13. The method of claim 12, wherein the compensation voltage is greater by 1V to 4V than the word line voltage.

14. A method of operating a semiconductor memory device, the method comprising:
applying an erase voltage to a well of a selected memory cell block in an erase operation;
floating a drain select line, a source select line, first dummy lines disposed between the source select line and word lines and second dummy lines disposed between the drain select line and the word lines;
applying a word line voltage to all word lines excluding outmost word lines adjacent to each of the first dummy lines and the second dummy lines; and
applying a compensation voltage greater than the word line voltage to the outmost word lines.

15. The method of claim 14, wherein the word line voltage is 0V.

16. The method of claim 15, wherein the compensation voltage is greater by 1V to 4V than the word line voltage.

17. The method of claim 14, further comprising:
applying the word line voltage to the outmost word lines after the erase operation is performed;
applying the compensation voltage to a dummy line adjacent to the outmost word line of the first dummy lines; and
erasing memory cells connected to the outmost word lines by applying the compensation voltage to a dummy line adjacent to the outmost word line of the second dummy lines.
